(19) United States
(12) Patent Application Publication
(10) Pub. No.: US 2024/0032387 A1
(43) Pub. Date: Jan. 25, 2024

(54) ELECTRONIC DEVICE

(71) Applicant: InnoLux Corporation, Miao-Li County (TW)

(72) Inventors: Chao-Chin SUNG, Miao-Li County (TW); Chueh-Yuan NIEN, Miao-Li County (TW)

(21) Appl. No.: 18/336,685

(22) Filed: Jun. 16, 2023

(30) Foreign Application Priority Data
Jul. 19, 2022 (CN) 202210848978.8

(51) Int. Cl. H10K 59/82; H01L 25/16; H01L 33/62

(52) U.S. Cl. CPC H10K 59/82; H01L 25/167; H01L 33/62; H01L 25/162; H10K 59/90

(57) ABSTRACT

An electronic device includes: a substrate; a conductive layer disposed on the substrate, wherein the conductive layer includes a plurality of branch portions; a plurality of bonding pads respectively disposed on the plurality of branch portions of the conductive layer; and an insulating layer disposed between the conductive layer and the plurality of bonding pads.

### CROSS-REFERENCE TO RELATED APPLICATIONS

This application claims the benefits of the Chinese Patent Application Serial Number 202210848978.8, filed on Jul. 19, 2022, the subject matter of which is incorporated herein by reference.

### BACKGROUND

### Field

The present disclosure relates to an electronic device. More specifically, the present disclosure relates to an electronic device with a conductive layer having specific design.

### Description of Related Art

With the advancement of technology and the needs of consumers, in addition to the development of display devices towards thinner, lighter and smaller, various manufacturers are also committed to developing display devices with narrow bezel designs to pursue a more refined edge visual sense.

In order to meet the requirement of narrow bezel designs, a flexible circuit board is generally used to connect the electronic device with an external power source or signal source. However, moisture or air easily enters from the joint between the flexible circuit board and the electronic device, causing oxidation or corrosion of the metal inside the electronic device, thereby causing short circuit or deterioration of the electronic device.

Therefore, it is desirable to provide an electronic device to improve the conventional defects.

### SUMMARY

The present disclosure provides an electronic device, comprising: a substrate; a conductive layer disposed on the substrate, wherein the conductive layer comprises a plurality of branch portions; a plurality of bonding pads respectively disposed on the plurality of branch portions of the conductive layer; and an insulating layer disposed between the conductive layer and the plurality of bonding pads.

Other novel features of the disclosure will become more apparent from the following detailed description when taken in conjunction with the accompanying drawings.

### BRIEF DESCRIPTION OF DRAWINGS

FIG. 1 is a schematic view of a part of an electronic device according to one embodiment of the present disclosure.

FIG. 2 is a partially enlarged view of FIG. 1.

FIG. 3 is a partially enlarged view of FIG. 2.

FIG. 4A and FIG. 4B are schematic views of a part of an electronic device according to one embodiment of the present disclosure.

FIG. 5 is a cross-sectional view of FIG. 4A and FIG. 4B along the line I-I′.

FIG. 6 is a cross-sectional view of FIG. 4A and FIG. 4B along the line II-II′.

FIG. 7 is a schematic view of a part of an electronic device according to one embodiment of the present disclosure.

FIG. 8 is a cross-sectional view of FIG. 7 along the line III-III′.

FIG. 9A and FIG. 9B are schematic views of a part of an electronic device according to one embodiment of the present disclosure.

FIG. 10 is a cross-sectional view of FIG. 9A and FIG. 9B along the line IV-IV′.

FIG. 11 is a schematic view of a part of an electronic device according to one embodiment of the present disclosure.

FIG. 12 is a cross-sectional view of FIG. 11 along the line V-V′.

FIG. 13 is a schematic view of a part of an electronic device according to one embodiment of the present disclosure.

FIG. 14 is a cross-sectional view of FIG. 13 along the line VI-VI′.

FIG. 15 is a cross-sectional view of FIG. 13 along the line VII-VII′.

FIG. 16 is a cross-sectional view of FIG. 3 along the line VIII-VIII′.

### DETAILED DESCRIPTION

The following is specific embodiments to illustrate the implementation of the present disclosure. Those who are familiar with this technique can easily understand the other advantages and effects of the present disclosure from the content disclosed in the present specification. The present disclosure can also be implemented or applied by other different specific embodiments, and various details in the present specification can also be modified and changed according to different viewpoints and applications without departing from the spirit of the present disclosure.

It should be noted that, in the present specification, when a component is described to have an element, it means that the component may have one or more of the elements, and it does not mean that the component has only one of the element, except otherwise specified. Furthermore, the ordinals recited in the specification and the claims such as “first”, “second” and so on are intended only to describe the elements claimed and imply or represent neither that the claimed elements have any proceeding ordinals, nor that sequence between one claimed element and another claimed element or between steps of a manufacturing method. The use of these ordinals is merely to differentiate one claimed element having a certain designation from another claimed element having the same designation.

In the specification and the appended claims of the present disclosure, certain words are used to refer to specific elements. Those skilled in the art should understand that electronic device manufacturers may refer to the same components by different names. The present specification does not intend to distinguish between elements that have the same function but have different names.

In the following description and claims, words such as “comprising”, “including”, “containing”, and “having” are open-ended words, so they should be interpreted as meaning “containing but not limited to . . . ”. Therefore, when the terms “comprising”, “including”, “containing” and/or “having” are used in the description of the present disclosure, they specify the existence of corresponding features, regions, steps, operations and/or components, but do not exclude the existence of one or more corresponding features, regions, steps, operations and/or components.

In the present specification, except otherwise specified, the terms (including technical and scientific terms) used herein have the meanings generally known by a person skilled in the art. It should be noted that, except otherwise specified in the embodiments of the present disclosure, these terms (for example, the terms defined in the generally used dictionary) should have the meanings identical to those known in the art, the background of the present disclosure or the context of the present specification, and should not be read by an ideal or over-formal way.

In addition, relative terms such as “below” or “under” and “on”, “above” or “over” may be used in the embodiments to describe the relative relationship between one element and another element in the drawings. It will be understood that if the device in the drawing was turned upside down, elements described on the “lower” side would then become elements described on the “upper” side. When a unit (for example, a layer or a region) is referred to as being “on” another unit, it can be directly on the another unit or there may be other units therebetween. Furthermore, when a unit is said to be “directly on another unit”, there is no unit therebetween. Moreover, when a unit is said to be “on another unit”, the two have a top-down relationship in a top view, and the unit can be disposed above or below the another unit, and the top-bottom relationship depends on the orientation of the device.

In addition, in some embodiments of the present disclosure, terms related to bonding and connection, such as “connection” and “interconnection”, unless otherwise specified, may mean that two components are in direct contact, or may also mean that two components are in indirect contact that other components may be contained between the two components. In addition, terms about bonding and connecting may also include the case where both two components are movable, or both two components are fixed.

In the present disclosure, the measurement of length and width may be achieved by using an optical microscope or from a cross-sectional image of an electron microscope; but the present disclosure is not limited thereto. In addition, the aforesaid measurement may be performed using the same optical microscope image or electron microscope image, or may be performed using a plurality of images. Furthermore, any two values or directions used for comparison may have certain errors. If the first value is equal to the second value, it implies that there may be an error of about 10% between the first value and the second value. If the first direction is perpendicular to the second direction, the angle between the first direction and the second direction may be between 80° and 100°. If the first direction is parallel to the second direction, the angle between the first direction and the second direction may be between 0° and 10°.

It should be noted that the technical solutions provided by different embodiments hereinafter may be replaced, combined or used in combination, so as to constitute another embodiment without violating the spirit of the present disclosure.

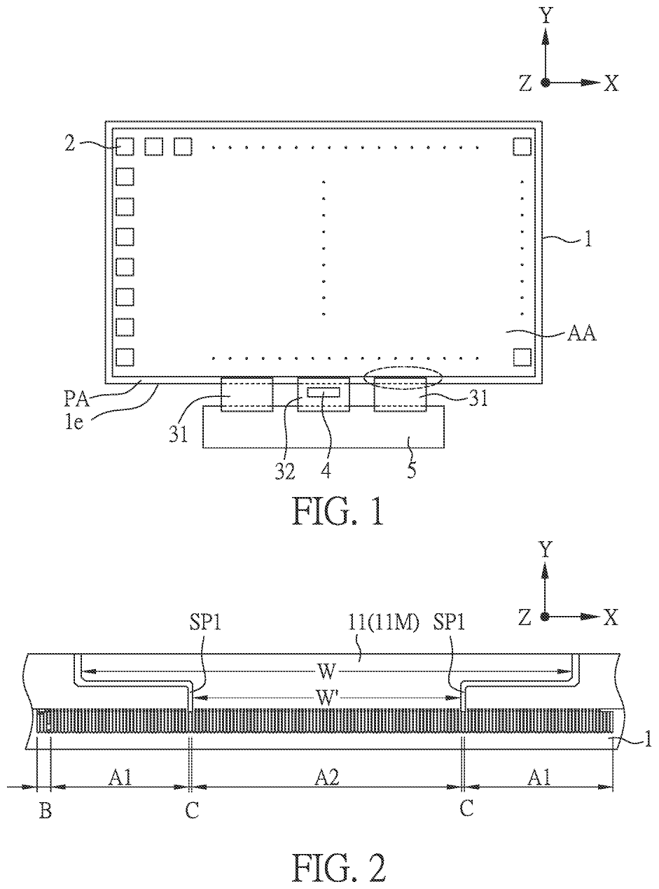

FIG. 1 is a schematic view of a part of an electronic device according to one embodiment of the present disclosure.

As shown in FIG. 1, the electronic device of one embodiment of the present disclosure comprises: a substrate 1; a plurality of light emitting units 2 disposed on the substrate 1; a first flexible circuit board 31 and a second flexible circuit board 32 respectively disposed on the substrate 1; an electronic unit 4 disposed on the second flexible circuit board 32 and electrically connected to the second flexible circuit board 32; and a circuit board 5, wherein the first flexible circuit board 31 and the second flexible circuit board 32 are respectively disposed on the circuit board 5. The circuit board 5 may be electrically connected to the circuits of the light emitting units 2 on the substrate 1 through the first flexible circuit board 31 and the second flexible circuit board 32, to respectively transmit power and signals to the light emitting units 2.

In addition, the electronic device of the present disclosure may further comprise a display device, an antenna device, a sensing device, a tiled device, a touch device or a combination thereof. For example, the electronic device of the present disclosure may comprise active components, passive components or a combination thereof, which may include diodes, transistors, capacitors, inductors, resistors or a combination thereof; but the present disclosure is not limited thereto. The electronic device of the present disclosure may include a display device, which may be, for example, a monitor, a mobile phone, a notebook computer, a video camera, a camera, a music player, a mobile navigation device, a television or other electronic devices that need to display images; but the present disclosure is not limited thereto. In one embodiment of the present disclosure, the electronic device may be a vehicle electronic device. It should be understood that, even not shown, the display panel may include upper and lower substrates, a display unit, a sealant, an alignment film, a polarizer, a light shielding layer, a color filter layer and/or a driving element, etc.; but the present disclosure is not limited thereto. The electronic devices include rollable, bendable or flexible electronic devices, but the present disclosure is not limited thereto. The display device may be a self-illuminating display device, the antenna device may be a liquid crystal type antenna device or a non-liquid crystal type antenna device, and the sensing device may be a sensing device that senses capacitance, light, heat or ultrasonic waves; but the present disclosure is not limited thereto. The sensing device may include a fingerprint sensing device, a visible light sensing device, an infrared light sensing device, an X-ray sensing device, but the present disclosure is not limited thereto. The tiled device may be, for example, a tiled display device or a tiled antenna device, but the present disclosure is not limited thereto. In addition, the shape of the electronic device may be rectangular, circular, polygonal, with curved edges, or other suitable shapes. The electronic device may have peripheral systems such as a processing system, a driving system, a control system, a light source system, and a shelf system to support a display device or a tiled device. It should be noted that the electronic device can be any combination mentioned above, but the present disclosure is not limited thereto.

In the present disclosure, the substrate 1 may be a quartz substrate, a glass substrate, a wafer, a sapphire substrate, a ceramic substrate or a substrate made of other materials. The substrate 1 may also be a flexible substrate, such as a plastic substrate or a film, and its material may include polycarbonate (PC), polyimide (PI), polypropylene (PP), polyethylene terephthalate (PET) or other plastic materials. The light emitting unit 2 may include a light-emitting diode, and the light-emitting diode may include, for example, an organic light emitting diode (OLED), a mini light emitting diode (mini LED), a micro light emitting diode (micro LED) or a quantum dot light emitting diode (may include QLED or QDLED), fluorescence materials, phosphors or other suitable materials, or a combination thereof; but the present disclosure is not limited thereto. The first flexible circuit board 31 and the second flexible circuit board 32 may be respectively, for example, a flexible printed circuit board (FPC). The electronic unit 4 may be, for example, an integrated circuit (IC). The circuit board 5 may be a rigid circuit board, such as a printed circuit board (PCB), but the disclosure is not limited thereto.

As shown in FIG. 1, the electronic device may include an active area AA and a peripheral area PA. In some embodiments, the peripheral area PA is disposed on at least one side of the active area AA. In the present embodiment, the peripheral area PA surrounds the active area AA, but the present disclosure is not limited thereto. The light emitting units 2 are disposed in the active area AA, and the first flexible circuit board 31 and the second flexible circuit board 32 are disposed in the peripheral area PA.

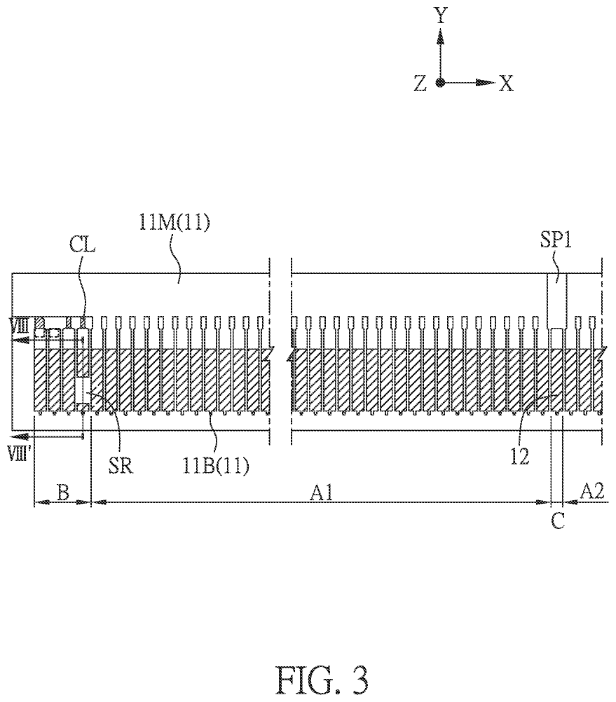

FIG. 2 is a partially enlarged view of FIG. 1. FIG. 3 is a partially enlarged view of FIG. 2. Herein, for the convenience of description, some elements, such as the first flexible circuit board 31 and the insulating layer, are omitted in FIG. 2 and FIG. 3.

As shown in FIG. 2 and FIG. 3, a conductive layer 11 is disposed on the substrate 1. In the peripheral area PA, the conductive layer 11 corresponding to the first flexible circuit board 31 may include two first main signal areas A1; a second main signal area A2 disposed between the first main signal areas A1, wherein there is a space SP1 between the first main signal area A1 and the second main signal area A2; a sub-signal area B disposed adjacent to the first main signal area A1; and a non-signal area C disposed at the space SP1 between the first main signal area A1 and the second main signal area A2. In the present embodiment, each main signal area (for example, the first main signal area A1 and the second main signal area A2) may comprise a main portion 11M and a plurality of branch portions 11B, wherein the plurality of branch portions 11B are respectively electrically connected to the main portion 11M. In some embodiment, the sub-signal area B may be disposed corresponding to the outermost side of the first flexible circuit board 31, but the disclosure is not limited thereto. In some embodiments, there may be a space SP1 between the first main signal area A1 and the second main signal area A2; or even not shown in the figure, there may be a space SP1 between the first main signal area A1 and the sub-signal area B; but the present disclosure is not limited thereto. The electronic device can receive power and signals through the first main signal area A1, the second main signal area A2, and the sub-signal area B to drive the light emitting unit 2. In the present embodiment, the sub-signal area B can receive signals through other conductive layers (such as the conductive layer CL) for signal testing. The non-signal area C can be insulated from the circuit on the substrate 1 for assembly alignment, which can reduce short circuit or damage to electronic devices when assembly deviation occurs.

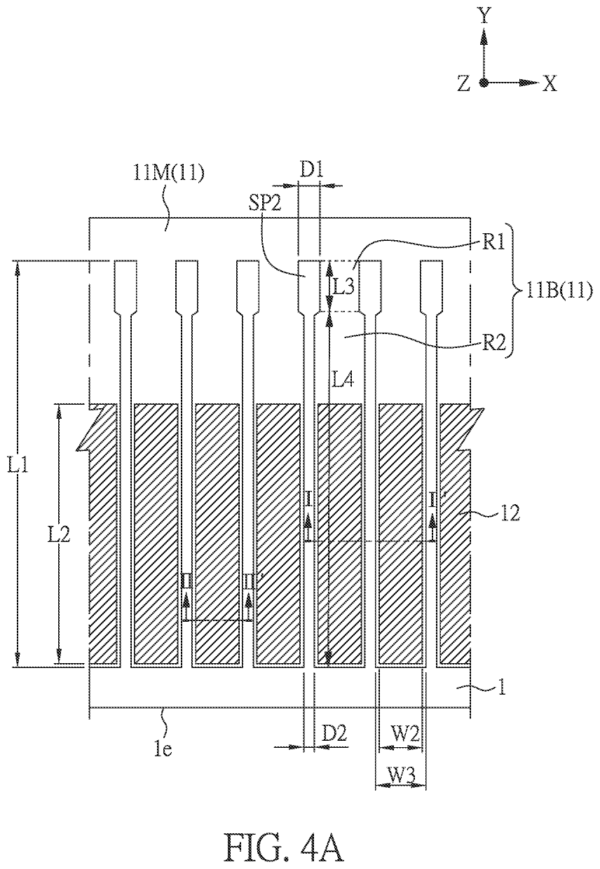

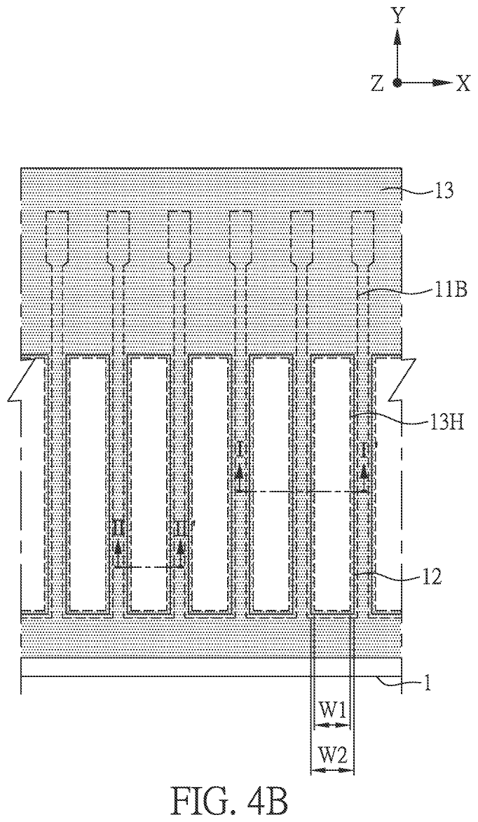

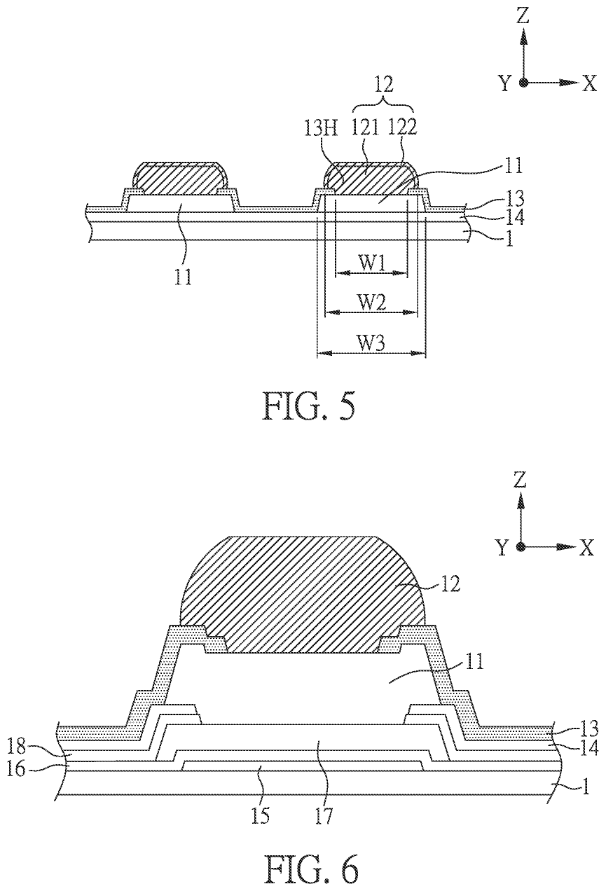

FIG. 4A and FIG. 4B are schematic views of a part of an electronic device according to one embodiment of the present disclosure. FIG. 5 is a cross-sectional view of FIG. 4A and FIG. 4B along the line I-I′. FIG. 6 is a cross-sectional view of FIG. 4A and FIG. 4B along the line II-IT. Herein, FIG. 4A and FIG. 4B are the schematic views of the same part of the electronic device, except that for the convenience of description, the insulating layer 13 is omitted in FIG. 4A, and only the filling pattern is marked for the insulating layer 13 in FIG. 4B.

In the present embodiments, FIG. 4A and FIG. 4B are schematic views of a part of the main signal area of the conductive layer 11. As shown in FIG. 4A, FIG. 4B and FIG. 5, the electronic device of the present embodiment may comprise: a substrate 1; a conductive layer 11 disposed on the substrate 1, wherein the conductive layer 11 comprises a main portion 11M and a plurality of branch portions 11B, and the branch portions 11B are respectively electrically connected to the main portion 11M, a plurality of bonding pads 12 respectively disposed on the branch portions 11B of the conductive layer 11; and an insulating layer 13 disposed between the conductive layer 11 and the bonding pads 12. In the present disclosure, through the design of the branch portions 11B of the conductive layer 11, the risk of deterioration of the conductive layer 11 can be reduced, thereby improving the reliability of the electronic device.

As shown in FIG. 2, the main portion 11M of the conductive layer 11 may extend along the second direction Y, and the main portion 11M may have different widths W, W′ in the first direction X. In addition, as shown in FIG. 4A, the plurality of branch portions 11B may be connected to the main portion 11M. Each branch portion 11B of the conductive layer 11 may extend along the second direction Y, the plurality of branch portions 11B may be arranged along the first direction X, and there is a space SP2 between two adjacent branch portions 11B. More specifically, each branch portion 11B may comprise a first region R1 and a second region R2, the second region R2 is closer to the edge 1e of the substrate 1 than the first region R1. The distance D1 between the first regions R1 of two adjacent branch portions 11B may be greater than the distance D2 between the second regions R2 of two adjacent branch portions 11B. In other words, the distance D1 between the first regions R1 of two adjacent branch portions 11B in the first direction X may be greater than the distance D2 between the second regions R2 of two adjacent branch portions 11B in the first direction X. In the present disclosure, the length L3 of the first region R1 may be less than the length L4 of the second region R2 in the second direction Y. Furthermore, in the second direction Y, each branch portion 11B may have a first length L1, and the bonding pad 12 corresponding to the branch portion 11B may have a second length L2, wherein the first length L1 may be greater than the second length L2.

In the present disclosure, the material of the conductive layer 11 may be, for example, a metal conductive material. The metal conductive material may include, for example, gold, nickel, platinum, copper, aluminum, molybdenum, tungsten, chromium, titanium, an alloy thereof, or a combination thereof; but the present disclosure is not limited thereto. In the present disclosure, the bonding pad 12 may include a single metal layer or a plurality of metal layers, and the material of the metal layer may include, for example, copper, aluminum, molybdenum, tungsten, gold, chromium, nickel, platinum, titanium, an alloy thereof or a combination thereof; but the present disclosure is not limited thereto. In one embodiment of the present disclosure, the bonding pads 12 may respectively include a plurality of metal layers comprising nickel and gold. In the present disclosure, the material of the insulating layer 13 is not particularly limited, for example, it may include silicon oxide, silicon oxynitride, silicon nitride, aluminum oxide, resin, polymer, photoresist, or a combination thereof, but the present disclosure is not limited thereto.

In the present disclosure, the first flexible circuit board 31 (as shown in FIG. 1) and/or the second flexible circuit board 32 (as shown in FIG. 1) may be electrically connected to the conductive layer 11 through the bonding pads 12 to transfer the signal provided by the circuit board 5 to the light emitting units 2. More specifically, as shown in FIG. 4B and FIG. 5, the insulating layer 13 may comprise an opening 13H exposing a part of the conductive layer 11, and the bonding pad 12 directly contacts the conductive layer 11 through the opening 13H of the insulating layer 13 to achieve the electrical connection. The bonding pad 12 can be used to improve the electrical connection effect between the first flexible circuit board 31 or the second flexible circuit board 32 and the conductive layer 11 on the substrate 1, or the bonding pad 12 can be used to protect the underlying conductive layer 11 to reduce the risk of deterioration of the conductive layer 11. In the present embodiment, as shown in FIG. 4B and FIG. 5, a projected area of the opening 13H of the insulating layer 13 on the substrate 1 may be less than a projected area of the bonding pad 12 on the substrate 1 in a normal direction Z of the substrate 1. More specifically, in the first direction X, the width W1 of the opening 13H of the insulating layer 13 may be less than the width W2 of the bonding pad 12.

In the present disclosure, as shown in FIG. 4A, a projected area of the bonding pad 12 on the substrate 1 is different from a projected area of the branch portion 11B of the conductive layer 11 on the substrate 1 in a normal direction Z of the substrate 1. More specifically, the projected area of the bonding pad 12 on the substrate 1 may be less than the projected area of the branch portion 11B of the conductive layer 11 corresponding to the bonding pad 12 on the substrate 1 in the normal direction Z of the substrate 1. Since the materials of the conductive layer 11 and the bonding pad 12 may be different, when the projected area of the bonding pad 12 on the substrate 1 is less than the projected area of the branch portion 11B on the substrate 1, the peeling of the conductive layer 11 due to different material stresses can be improved. In addition, as shown in FIG. 4A and FIG. 5, the width W3 of the branch portion 11B may be greater than the width W2 of the bonding pad 12.

In one embodiment of the present disclosure, as shown in FIG. 5, the bonding pad 12 may comprise a plurality of metal layers, for example, a first metal layer 121 and a second metal layer 122, and the first metal layer 121 is disposed between the second metal layer 122 and the conductive layer 11. The second metal layer 122 can be used to protect the first metal layer 121 to reduce the contact of the first metal layer 121 with air or moisture, and reduce the risk of deterioration of the first metal layer 121. In the present embodiment, the material of the first metal layer 121 may include nickel, the material of the second metal layer 122 may include gold, but the disclosure is not limited thereto. In the present disclosure, the thickness of the first metal layer 121 may be greater than the thickness of the second metal layer 122. In addition, the electronic device may further comprise another insulating layer 14 disposed between the substrate 1 and the conductive layer 11. Herein, the material of the insulating layer 14 may be the same as or different from that of the insulating layer 13, which will not be repeated here.

In the present disclosure, there may be different stacking designs at the branch portion 11B of the conductive layer 11 (as shown in FIG. 4A). As shown in FIG. 6, in one embodiment of the present disclosure, the electronic device may comprise: a semiconductor layer 15 disposed on the substrate 1; a first insulating layer 16 disposed on the semiconductor layer 15; another conductive layer 17 disposed on the first insulating layer 16; and a second insulating layer 18 disposed on the conductive layer 17, wherein the insulating layer 14, the conductive layer 11, the insulating layer 13 and the bonding pad 12 are sequentially disposed on the second insulating layer 18, and the conductive layer 11 may be electrically connected to the conductive layer 17. It should be understood that, in other embodiments of the present disclosure, the stacking design at the branch portion 11B of the conductive layer 11 (as shown in FIG. 4A) may be changed according to the need.

In the present embodiment, the material of the semiconductor layer 15 may include amorphous silicon or poly-silicon, but the present disclosure is not limited thereto. The material of the first insulating layer 16 and the second insulating layer 18 may be the same as or different from the material of the insulating layer 13, which will not be repeated here. The material of the conductive layer 17 may be the same as or different from that of the conductive layer 11 or the bonding pad 12, which will not be repeated here.

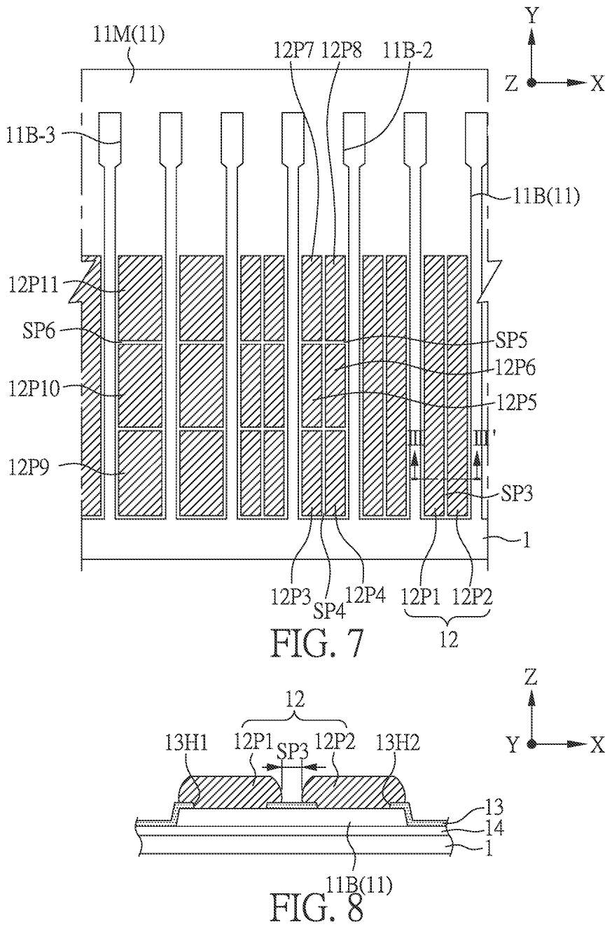

FIG. 7 is a schematic view of a part of an electronic device according to one embodiment of the present disclosure. FIG. 8 is a cross-sectional view of FIG. 7 along the line III-III′. For convenience of illustration, the insulating layer 13 is omitted in FIG. 7, wherein the electronic device of FIG. 7 is similar to that of FIG. 4A except for the following differences.

As shown in FIG. 7 and FIG. 8, the bonding pad 12 may comprise a plurality of sub-bonding pads such as a first sub-bonding pad 12P1 and a second sub-bonding pad 12P2 respectively disposed on the same branch portion 11B of the conductive layer 11, and there is a space SP3 extending along the second direction Y between the first sub-bonding pad 12P1 and the second sub-bonding pad 12P2. When the bonding pad 12 is prepared by using a material with high hardness, the bonding effect between the first flexible circuit board 31 (as shown in FIG. 1) and the bonding pad 12 may be poor. When the bonding pad 12 includes a plurality of sub-bonding pads, the stress occurred during bonding of the first flexible circuit board 31 (as shown in FIG. 1) can be dispersed, and the bonding effect can be improved. Herein, the materials of the first sub-bonding pad 12P1 and the second sub-bonding pad 12P2 may be the same or different from each other, which will not be repeated here.

In the present disclosure, the bonding pad 12 on each branch portion 11B may respectively comprise a plurality of sub-bonding pads, and the sub-bonding pads on each branch portion 11B may have the same or different designs. For example, in the present embodiment, as shown in FIG. 7, the sub-bonding pads on the branch portions 11B may have designs different from the sub-bonding pads on the branch portion 11B-2 and/or the branch portion 11B-3. However, in other embodiments of the present disclosure, the sub-bonding pads on each branch portions 11B, 11B-2 and 11B-3 may have a similar design. In the present disclosure, as shown in FIG. 7, the branch portion 11B-2 may be disposed with a plurality of sub-bonding pads 12P3, 12P4, 12P5, 12P6, 12P7, and 12P8. There is a space SP4 extending along the second direction Y between the sub-bonding pad 12P3 and the sub-bonding pad 12P4, between the sub-bonding pad 12P5 and the sub-bonding pad 12P6, and between the sub-bonding pad 12P7 and the sub-bonding pad 12P8. There is a space SP5 extending along the first direction X between the sub-bonding pad 12P3 and the sub-bonding pad 12P5, between the sub-bonding pad 12P5 and the sub-bonding pad 12P7, between the sub-bonding pad 12P4 and the sub-bonding pad 12P6, and between the sub-bonding pad 12P6 and the 12P8. In addition, the branch portion 11B-3 may be disposed with a plurality of sub-bonding pads 12P9, 12P10 and 12P11. There is a space SP6 extending along the first direction X between the sub-bonding pad 12P9 and the sub-bonding pad 12P10, and between the sub-bonding pad 12P10 and the sub-bonding pad 12P11.

In addition, as shown in FIG. 8, the insulating layer 13 comprises a first opening 13H1 and a second opening 13H2 respectively exposing a part of the branch portion 11B of the conductive layer 11, wherein the first sub-bonding pad 12P1 is electrically connected to the conductive layer 11 through the first opening 13H1 of the insulating layer 13, and the second sub-bonding pad 12P2 is electrically connected to the conductive layer 11 through the second opening 13H2 of the insulating layer 13.

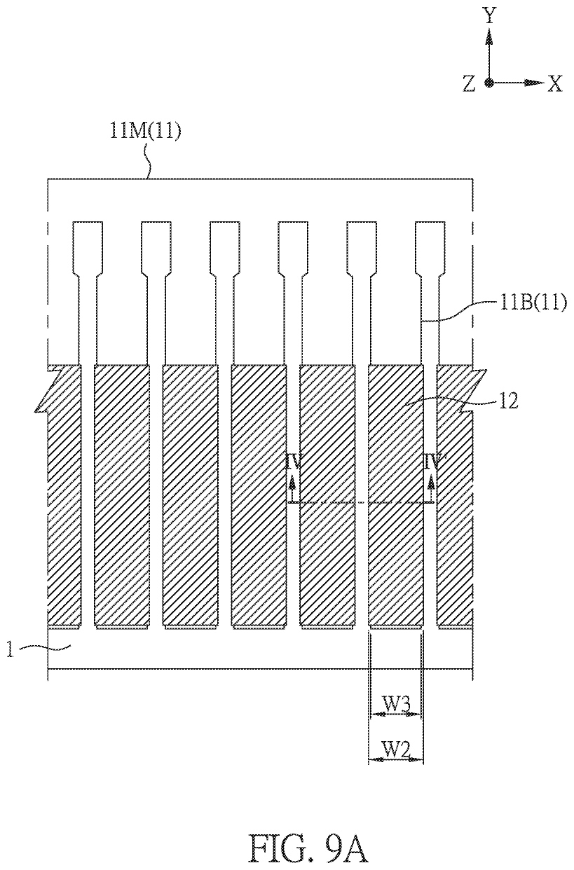

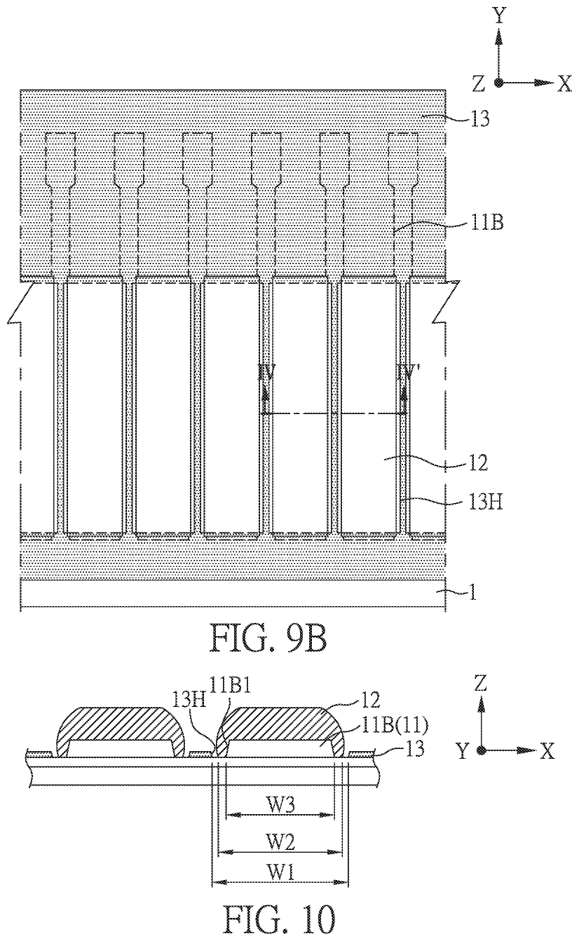

FIG. 9A and FIG. 9B are schematic views of a part of an electronic device according to one embodiment of the present disclosure. FIG. 10 is a cross-sectional view of FIG. 9A and FIG. 9B along the line IV-IV′. Herein, FIG. 9A and FIG. 9B are the schematic views of the same part of the electronic device, except that for the convenience of description, the insulating layer 13 is omitted in FIG. 9A, and only the filling pattern is marked for the insulating layer 13 in FIG. 9B. In addition, the electronic device of FIG. 9A is similar to that of FIG. 4A except for the following differences.

In the present embodiment, as shown in FIG. 9A and FIG. 10, the width W2 of the bonding pad 12 is greater than the width W3 of the branch portion 11B in the first direction X. More specifically, in a cross-sectional view, the bonding pad 12 may cover a sidewall 11B1 of the branch portion 11B. Therefore, the contact of the branch portion 11B with air or moisture can be reduced, reducing the risk of deterioration of the conductive layer 11, thereby improving the reliability of the electronic device.

In addition, as shown in FIG. 9B and FIG. 10, the insulating layer 13 may comprise an opening 13H, and the branch portion 11B of the conductive layer 11 and the bonding pad 12 are respectively disposed in the opening 13H. More specifically, in the first direction X, the width W1 of the opening 13H of the insulating layer 13 may be greater than the width W3 of the branch portion 11B and the width W2 of the bonding pad 12 respectively. In other words, in a cross-sectional view, as shown in FIG. 10, the bonding pad 12 may not be in contact with the insulating layer 13, but the present disclosure is not limited thereto.

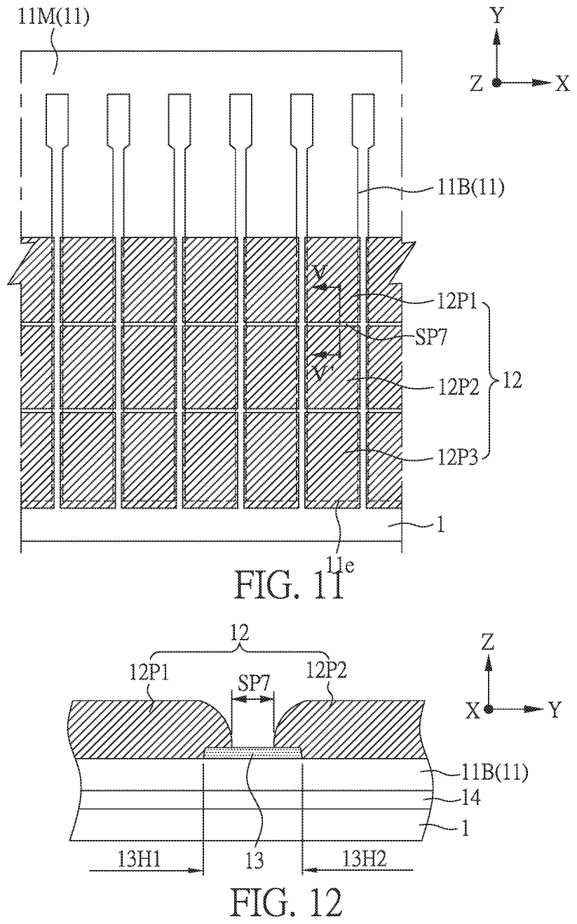

FIG. 11 is a schematic view of a part of an electronic device according to one embodiment of the present disclosure. FIG. 12 is a cross-sectional view of FIG. 11 along the line V-V′. For convenience of illustration, the insulating layer 13 is omitted in FIG. 11, and the electronic device of FIG. 11 is similar to that of FIG. 9A except for the following differences.

As shown in FIG. 11, the bonding pad 12 may comprise a plurality of sub-bonding pads such as a first sub-bonding pad 12P1, a second sub-bonding pad 12P2 and a third sub-bonding pad 12P3 respectively disposed on the same branch portion 11B of the branch portion 11B. The first sub-bonding pad 12P1, the second sub-bonding pad 12P2 and the third sub-bonding pad 12P3 are arranged along the second direction Y, and there is a space SP7 extending along the first direction X between each other arranged in the second direction Y. When the bonding pad 12 is prepared by using a material with high hardness, the bonding effect between the first flexible circuit board 31 (as shown in FIG. 1) and the bonding pad 12 may be poor. When the bonding pad 12 includes a plurality of sub-bonding pads, the stress occurred during bonding of the first flexible circuit board 31 (as shown in FIG. 1) can be dispersed, and the bonding effect can be improved. Herein, the materials of the first sub-bonding pad 12P1, the second sub-bonding pad 12P2 and the third sub-bonding pad 12P3 may be the same or different from each other, which will not be repeated here.

In the present disclosure, the bonding pad 12 on each branch portion 11B may respectively include a plurality of sub-bonding pads, and the sub-bonding pads on each branch portion 11B may have the same or different designs. For example, in the present embodiment, as shown in FIG. 11, the sub-bonding pads on each branch portion 11B may have a similar design. However, in other embodiments of the present disclosure, the sub-bonding pads on each branch portion 11B may have different designs. In addition, in the present embodiment, as shown in FIG. 11, the third sub-bonding pad 12P3 may be overlapped with the end of the branch portion 11B in the normal direction Z of the substrate 1. More specifically, the third sub-bonding pad 12P3 may protrude from an edge 11e of the branch portion 11B in the second direction Y, but the present disclosure is not limited thereto.

In the present disclosure, as shown in FIG. 12, the insulating layer 13 may comprise a first opening 13H1 and a second opening 13H2 respectively exposing a part of the branch portion 11B of the conductive layer 11, wherein the first sub-bonding pad 12P1 is electrically connected to the conductive layer 11 through the first opening 13H1 of the insulating layer 13, and the second sub-bonding pad 12P2 is electrically connected to the conductive layer 11 through the second opening 13H2 of the insulating layer 13.

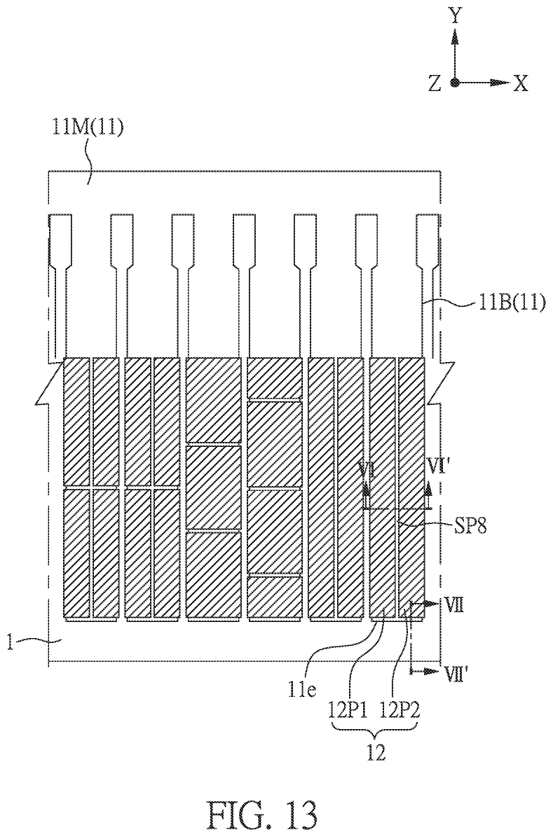

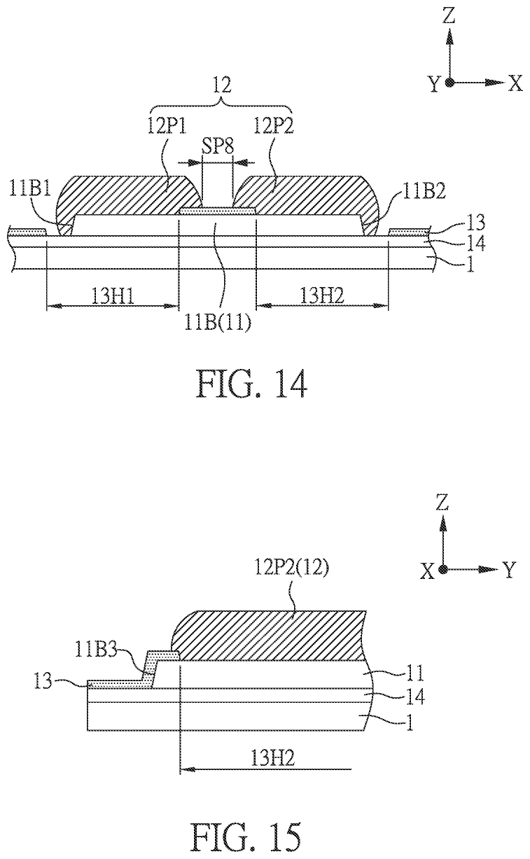

FIG. 13 is a schematic view of a part of an electronic device according to one embodiment of the present disclosure. FIG. 14 is a cross-sectional view of FIG. 13 along the line VI-VI′. FIG. 15 is a cross-sectional view of FIG. 13 along the line VII-VII′. For convenience of illustration, the insulating layer 13 is omitted in FIG. 13, and the electronic device of FIG. 13 is similar to that of FIG. 11 except for the following differences.

In the present embodiment, as shown in FIG. 13, the sub-bonding pads on the branch portion 11B may have different designs. For example, the bonding pad 12 may include a plurality of sub-bonding pads, such as a first sub-bonding pad 12P1 and a second sub-bonding pad 12P2 respectively disposed on the same branch portion 11B of the conductive layer 11, wherein the first sub-bonding pad 12P1 and the second sub-bonding pad 12P1 can be arranged along the first direction X, and there is a space SP8 extending along the second direction Y between the first sub-bonding pad 12P1 and the second sub-bonding pad 12P2 in the first direction X. However, in other embodiments of the present disclosure, the first sub-bonding pad 12P1 and the second sub-bonding pad 12P2 may be arranged along the second direction Y, and there may be a space extending along the first direction X between each other arranged in the second direction Y.

In the present embodiment, as shown in FIG. 14, the insulating layer 13 may comprise a first opening 13H1 and a second opening 13H2 respectively exposing a part of the branch portion 11B of the conductive layer 11, wherein the first sub-bonding pad 12P1 is electrically connected to the conductive layer 11 through the first opening 13H1 of the insulating layer 13, and the second sub-bonding pad 12P2 is electrically connected to the conductive layer 11 through the second opening 13H2 of the insulating layer 13. In addition, in the cross-sectional view of the first direction X, the first sub-bonding pad 12P1 may cover a sidewall 11B1 of the branch portion 11B, and the second sub-bonding pad 12P2 may cover another sidewall 11B2 of the branch portion 11B, wherein the sidewall 11B1 is opposite to the sidewall 11B2. In other words, the projection of the first sub-bonding pad 12P1 on the substrate 1 is partially overlapped with the projection of the first opening 13H1 on the substrate 1, and the projection of the second sub-bonding pad 12P2 on the substrate 1 is partially overlapped with the projection of the second opening 13H2 on the substrate 1 in the normal direction Z of the substrate 1.

In addition, in the present embodiment, as shown in FIG. 13, the first sub-bonding pad 12P1 and the second sub-bonding pad 12P2 are not overlapped with the end of the branch portion 11B respectively, in the normal direction Z of the substrate 1. More specifically, the edge 11e of the branch portion 11B may protrude from the first sub-bonding pad 12P1 and the second sub-bonding pad 12P2 in the second direction Y. Therefore, as shown in FIG. 15, the bonding pad 12 does not cover the sidewall 11B3 of the branch portion 11B in the cross-sectional view of line VII-VII′.

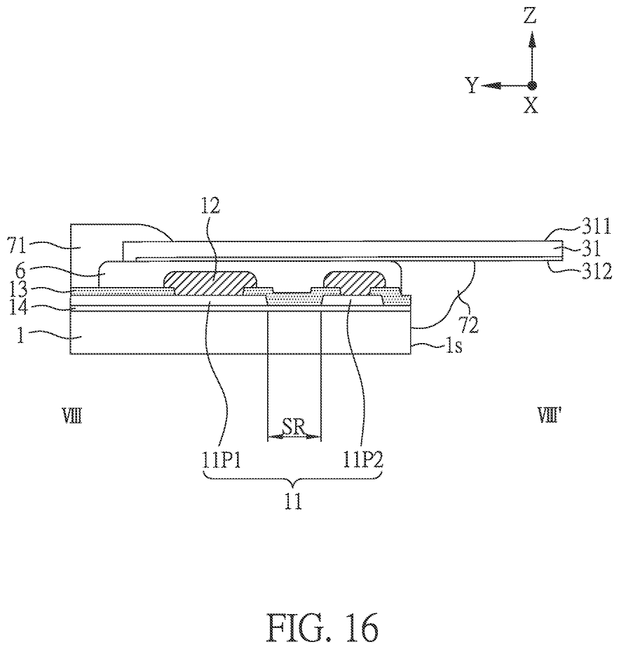

FIG. 16 is a cross-sectional view of FIG. 3 along the line VIII-VIII′.

As shown in FIG. 16, the first flexible circuit board 31 may be electrically connected to the bonding pads 12 and the conductive layer 11 on the substrate 1 through a conductive adhesive layer 6 for signal transmission. In the present embodiment, the electronic device may further include an adhesive layer 71 disposed on the first flexible circuit board 31, wherein a part of the adhesive layer 71 may be in contact with the insulating layer 13 and the conductive adhesive layer 6. In addition, in the present embodiment, the electronic device may further include another adhesive layer 72 disposed on the first flexible circuit board 31, and a part of the adhesive layer 72 may be in contact with a side surface 1s of the substrate 1. More specifically, the first flexible circuit board 31 has a first surface 311 and a second surface 312, the first surface 311 is opposite to the second surface 312, and the second surface 312 faces the substrate 1. The adhesive layer 71 is disposed on the first surface 311 of the first flexible circuit board 31, and the adhesive layer 72 is disposed on the second surface 312 of the first flexible circuit board 31. With the arrangement of the adhesive layer 71 and/or the adhesive layer 72, the entry of external air or moisture can be further blocked, and the risk of deterioration of the conductive layer 11 can be reduced.

In the present disclosure, the conductive adhesive layer 6 may be, for example, an anisotropic conductive film (ACF). The adhesive layer 71 and the adhesive layer 72 may respectively comprise a non-conductive adhesive material, and the non-conductive adhesive material include glass glue, optical glue, silicon glue, tape, hot melt glue, AB glue, two-component adhesive, polymer glue, resin or a combination thereof, but the present disclosure is not limited thereto.

In addition, as shown in FIG. 3 and FIG. 16, in the sub-signal area B of the substrate 1, the branch portion 11B of the conductive layer 11 may comprise a first portion 11P1 and a second portion 11P2, and there is a space SR between the first portion 11P1 and the second portion 11P2. The alignment between the substrate 1 and the flexible circuit board can be observed through the space SR, so as to improve the bonding effect. In some embodiments, the first portion 11P1 can be electrically connected to other conductive layers (such as the conductive layer CL) to receive signals for signal testing.

Although the present disclosure has been explained in relation to its embodiment, it is to be understood that many other possible modifications and variations can be made without departing from the spirit and scope of the disclosure as hereinafter claimed.

1. An electronic device, comprising:
a substrate;
a conductive layer disposed on the substrate, wherein the conductive layer comprises a plurality of branch portions;
a plurality of bonding pads respectively disposed on the plurality of branch portions of the conductive layer; and
an insulating layer disposed between the conductive layer and the plurality of bonding pads.

2. The electronic device of claim 1, wherein a projected area of one of the plurality of bonding pads on the substrate is different from a projected area of one of the plurality of branch portions of the conductive layer on the substrate in a normal direction of the substrate.

3. The electronic device of claim 1, wherein the insulating layer comprises an opening exposing a part of the conductive layer, and one of the plurality of bonding pads directly contacts the conductive layer through the opening of the insulating layer.

4. The electronic device of claim 1, further comprising another insulating layer disposed between the substrate and the conductive layer.

5. The electronic device of claim 1, wherein one of the plurality of bonding pads comprises a plurality of metal layers.

6. The electronic device of claim 1, wherein one of the plurality of bonding pads comprises a first sub-bonding pad and a second sub-bonding pad, and there is a space between the first sub-bonding pad and the second sub-bonding pad.

7. The electronic device of claim 1, wherein a width of one of the plurality of bonding pads is greater than a width of one of the plurality of branch portions of the conductive layer in a cross-sectional view.

8. The electronic device of claim 1, wherein one of the plurality of bonding pads covers a sidewall of one of the plurality of branch portions of the conductive layer in a cross-sectional view.

9. The electronic device of claim 1, wherein the electronic device is a vehicle electronic device.

10. The electronic device of claim 1, wherein one of the plurality of branch portions comprises a first portion and a second portion, and there is a space between the first portion and the second portion.

11. The electronic device of claim 1, further comprising a flexible circuit board disposed on the substrate and electrically connected to at least one of the plurality of bonding pads and the conductive layer.

12. The electronic device of claim 11, wherein the flexible circuit board is electrically connected to the at least one of the plurality of bonding pads and the conductive layer through a conductive adhesive layer.

13. The electronic device of claim 12, further comprising: a plurality of light emitting units disposed on the substrate; and a circuit board, wherein the circuit board is electrically connects to the plurality of light emitting units through the flexible circuit board.

14. The electronic device of claim 12, further comprising an adhesive layer disposed on the flexible circuit board, wherein a part of the adhesive layer is in contact with the insulating layer.

15. The electronic device of claim 12, further comprising another adhesive layer disposed on the flexible circuit board, wherein a part of the another adhesive layer is in contact with a side surface of the substrate.

16. The electronic device of claim 1, wherein the conductive layer further comprises a main portion, and at least one of the plurality of branch portions is electrically connected to the main portion.

17. The electronic device of claim 1, further comprising a semiconductor layer disposed on the substrate, and the conductive layer is disposed on the semiconductor layer.

18. The electronic device of claim 1, wherein one of the plurality of branch portions has a first length, one of the plurality of bonding pads has a second length, and the first length is greater than the second length.

19. The electronic device of claim 1, wherein two adjacent branch portions of the plurality of branch portions respectively comprise a first region and a second region, the second region is closer to an edge of the substrate than the first region, and a distance between the first regions of the two adjacent branch portions is greater than a distance between the second regions of the two adjacent branch portions.

20. The electronic device of claim 19, wherein a length of the first region is less than a length of the second region.
